(19) United States
(12) Patent Application Publication
(10) Pub. No.: US 2009/0053482 A1
(43) Pub. Date: Feb. 26, 2009

(54) METHOD OF REDUCING IMAGE FADE

(76) Inventors: Julie Baker, Leavesden (GB); Nicholas J. Dartnell, Longstanton (GB)

Correspondence Address: David A. Novais;Patent Legal Staff, Eastman Kodak Company, 343 State Street, Rochester, NY, 14650-2201, US

(21) Appl. No.: 12/195,460

(22) Filed: Aug. 21, 2008

(30) Foreign Application Priority Data
Aug. 25, 2007 (GB) 0716653.1

(51) Int. Cl. C23C 16/00; B32B 5/00; C01F 7/02

(52) U.S. Cl. 428/195.1; 427/255.28; 423/625

(57) ABSTRACT

A method of reducing dye fade of a printed inkjet image comprises the step of depositing a layer of Al₂O₃ over the image. Also contemplated is an inkjet printer that contains a depositable source of Al₂O₃.

### FIELD OF THE INVENTION

This invention relates to the reduction of image fade of inkjet printed images when using dye based inks.

### BACKGROUND OF THE INVENTION

Inkjet inks typically comprise an ink vehicle and a colorant, which may be a dye or a pigment. Dye based inkjet inks are usually water soluble dyes and often create images which fade over time, especially when used in conjunction with porous inkjet media. Pigment based inks however form fade resistant images. It is often the case that inkjet ‘systems’ are developed such that the ink and media work well together to form images that do not fade over time.

However, consumers may not always use the correct ink for the system. This could result in images being printed which exhibit poor image fade.

Most commercial photo-quality inkjet receivers can be classified in one of two categories according to whether the principal component material forms a layer that is “porous” or “non-porous” in nature. Porous receivers comprise of inorganic materials with a polymeric binder, which absorb ink by capillary action. Because they absorb ink very quickly they have become the preferred technology as the speed of printing and quantity of ink being laid down is increasing. At the same time, some manufacturers of desktop printers are beginning to use pigmented inks while others are maintaining their dye based ink systems, resulting in a desire to have one inkjet receiver that performs well with both types of ink.

It is therefore of some importance to be able to reduce the image fade seen when dye based inks are used, especially when used with the preferred porous inkjet media.

There are many known methods of the use of fusible printing media to reduce fade. One example of this is “Fusible printing media,” US 2006/0068178. The method involves the steps of formulating the coating, applying the coating to the recording media, drying the coating, forming an image on the recording media, drying the image and fusing the coating, rendering the image fade resistant.

A second method of reducing image fade is disclosed in “Inkjet printing media,” US 2005/0287312. This patent application discloses a method of improving image fastness comprising the steps of coating a media substrate with a porous coating composition of metal oxide particulates to form a porous ink receiving layer and coating the porous ink-receiving layer with an aqueous overcoat composition to form a discontinuous film that is configured with pores to allow an ink to reach the porous ink receiving layer while improving image fade.

A third method of reducing image fade is disclosed in “Method for forming image on inkjet recording material,” JP 2003103919. This describes the steps of providing a resin coating layer on one side of the base paper and providing an ink accepting layer containing inorganic fine particles and a hydrophobic binder on the opposite surface, forming the image on the ink accepting layer and then providing a transparent resin protective layer on the image forming surface.

A fourth method of reducing image fade is disclosed in “Additive for inkjet printing, recording solution, method for preventing discoloration and fading of image, and recording sheet,” U.S. Pat. No. 6,362,348. This patent discloses the incorporation of a stabilised ascorbic acid derivative in either the ink or the recording medium to reduce image fade.

### PROBLEM TO BE SOLVED BY THE INVENTION

When inks are used to form an image, poor image fade can be seen, especially when dye-based inks are used with porous inkjet media. The present invention aims to reduce the fade.

### SUMMARY OF THE INVENTION

According to the present invention there is provided a method of reducing image fade of a printed inkjet image comprising the step of depositing a layer of Al₂O₃ over the image. Also contemplated is an inkjet printer that contains a depositable source of Al₂O₃.

### ADVANTAGEOUS EFFECT OF THE INVENTION

The present invention provides a printer and method to reduce image fade, especially when dye based inks are used to create an inkjet image, and especially when used with porous inkjet receivers. The invention is compatible with a roll to roll manufacturing process.

### BRIEF DESCRIPTION OF THE DRAWINGS

The invention will now be described with reference to the accompanying drawings in which:

FIG. 1 is a flow chart describing the steps of an atomic layer deposition (ALD) process that may be used in the present invention;

FIG. 2 is a cross-sectional side view of an embodiment of a distribution manifold for atomic layer deposition that can be used in the present process;

FIG. 3 is a cross-sectional side view of an embodiment of the distribution of gaseous materials to a substrate that is subject to thin film deposition; and

FIGS. 4A and 4B are cross-sectional views of an embodiment of the distribution of gaseous materials schematically showing the accompanying deposition operation.

### DETAILED DESCRIPTION OF THE INVENTION

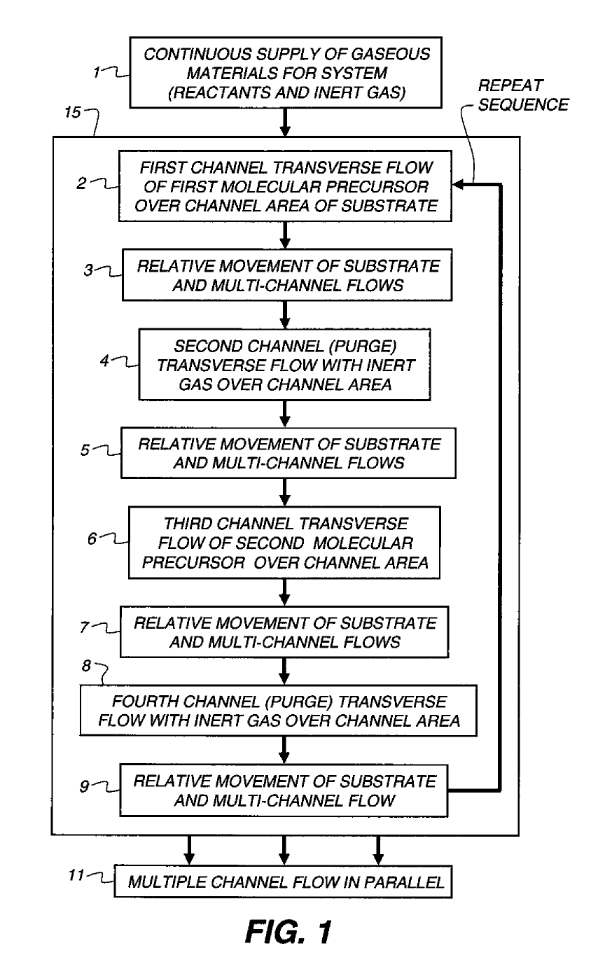

FIG. 1 is a generalized step diagram of a process for practicing the present invention. Two reactive gases are used, a first molecular precursor and a second molecular precursor. Gases are supplied from a gas source and can be delivered to the substrate, for example, via a distribution manifold. Metering and valving apparatus for providing gaseous materials to the distribution manifold can be used.

As shown in Step 1, a continuous supply of gaseous materials for the system is provided for depositing a thin film of material on a substrate. The Steps in Sequence 15 are sequentially applied. In Step 2, with respect to a given area of the substrate (referred to as the channel area), a first molecular precursor or reactive gaseous material is directed to flow in a first channel transversely over the channel area of the substrate and reacts therewith. In Step 3 relative movement of the substrate and the multi-channel flows in the system occurs, which sets the stage for Step 4, in which second channel (purge) flow with inert gas occurs over the given channel area. Then, in Step 5, relative movement of the substrate and the multi-channel flows sets the stage for Step 6, in which the given channel area is subjected to atomic layer deposition in which a second molecular precursor now transversely flows (substantially parallel to the surface of the substrate) over the given channel area of the substrate and reacts with the previous layer on the substrate to produce (theoretically) a monolayer of a desired material. Often in such processes, a first molecular precursor is a metal-containing compound in gas form (for example, a metallic compound such as trimethyl aluminium) and the material deposited is a metal-containing compound (for example aluminium oxide). In such an embodiment, the second molecular precursor can be, for example, a non-metallic oxidizing compound or hydrolyzing compound, e.g. water.

In Step 7, relative movement of the substrate and the multi-channel flows then sets the stage for Step 8 in which again an inert gas is used, this time to sweep excess second molecular precursor from the given channel area from the previous Step 6. In Step 9, relative movement of the substrate and the multi-channels occurs again, which sets the stage for a repeat sequence, back to Step 2. The cycle is repeated as many times as is necessary to establish a desired film or layer. The steps may be repeated with respect to a given channel area of the substrate, corresponding to the area covered by a flow channel. Meanwhile the various channels are being supplied with the necessary gaseous materials in Step 1. Simultaneous with the sequence of box 15 in FIG. 1, other adjacent channel areas are being processed simultaneously, which results in multiple channel flows in parallel, as indicated in overall Step 11.

The primary purpose of the second molecular precursor is to condition the substrate surface back toward reactivity with the first molecular precursor. The second molecular precursor also provides material as a molecular gas to combine with one or more metal compounds at the surface, forming compounds such as an oxide, nitride, sulfide, etc, with the freshly deposited metal-containing precursor

The continuous ALD purge does not need to use a vacuum purge to remove a molecular precursor after applying it to the substrate.

Assuming that two reactant gases, AX and BY, are used, when the reaction gas AX flow is supplied and flowed over a given substrate area, atoms of the reaction gas AX are chemically adsorbed on a substrate, resulting in a layer of A and a surface of ligand X (associative chemisorptions) (Step 2). Then, the remaining reaction gas AX is purged with an inert gas (Step 4). Then, the flow of reaction gas BY and a chemical reaction between AX (surface) and BY (gas) occurs, resulting in a molecular layer of AB on the substrate (dissociative chemisorptions) (Step 6). The remaining gas BY and by-products of the reaction are purged (Step 8). The thickness of the thin film can be increased by repeating the process cycle (steps 2-9).

Because the film can be deposited one monolayer at a time it tends to be conformal and have uniform thickness.

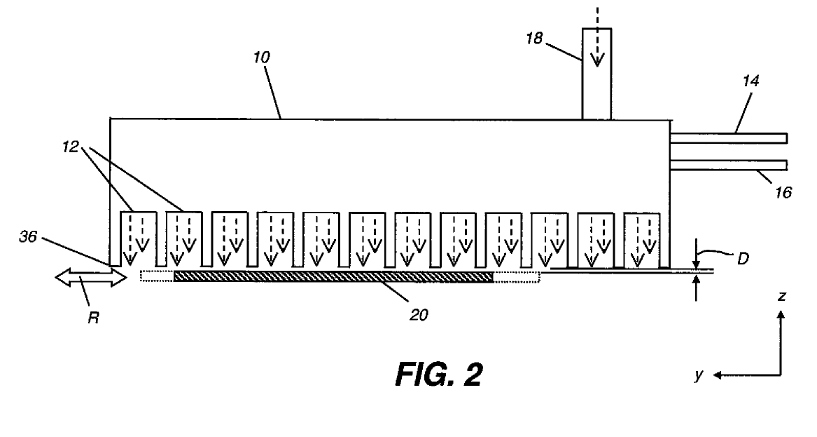

Referring now to FIG. 2, there is shown a cross-sectional side view of one embodiment of a distribution manifold 10 that can be used in the present process for atomic layer deposition onto a substrate 20. Distribution manifold 10 has a gas inlet port 14 for accepting a first gaseous material, a gas inlet port 16 for accepting a second gaseous material, and a gas inlet port 18 for accepting a third gaseous material. These gases are emitted at an output face 36 via output channels 12, having a structural arrangement described subsequently. The arrows in FIG. 2 refer to the diffusive transport of the gaseous material, and not the flow, received from an output channel. The flow is substantially directed out of the page of the figure.

Gas inlet ports 14 and 16 are adapted to accept first and second gases that react sequentially on the substrate surface to effect ALD deposition, and gas inlet port 18 receives a purge gas that is inert with respect to the first and second gases. Distribution manifold 10 is spaced a distance D from substrate 20, provided on a substrate support. Reciprocating motion can be provided between substrate 20 and distribution manifold 10, either by movement of substrate 20, by movement of distribution manifold 10, or by movement of both substrate 20 and distribution manifold 10. In the particular embodiment shown in FIG. 2, substrate 20 is moved across output face 36 in reciprocating fashion, as indicated by the arrow R and by phantom outlines to the right and left of substrate 20 in FIG. 2. It should be noted that reciprocating motion is not always required for thin-film deposition using distribution manifold 10. Other types of relative motion between substrate 20 and distribution manifold 10 could also be provided, such as movement of either substrate 20 or distribution manifold 10 in one or more directions.

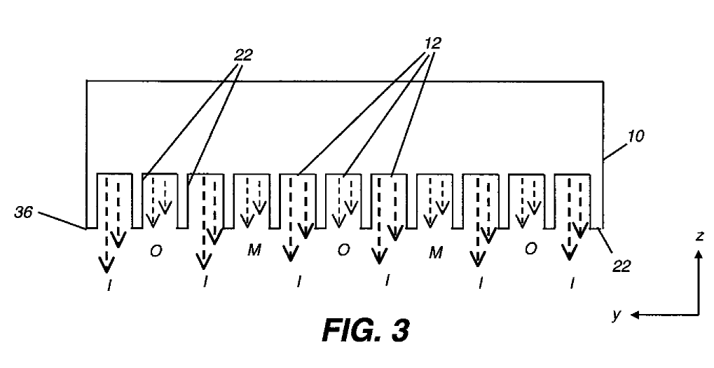

The cross-sectional view of FIG. 3 shows gas flows emitted over a portion of front face 36 of distribution manifold 10. In this particular arrangement, each output channel 12 is in gaseous flow communication with one of gas inlet ports 14, 16 or 18 seen in FIG. 2. Each output channel 12 delivers typically a first reactant gaseous material O, or a second reactant gaseous material M, or a third inert gaseous material I.

FIG. 3 shows a relatively basic or simple arrangement of gases. It is possible that a plurality of non-metal deposition precursors (like material O) or a plurality of metal-containing precursor materials (like material M) may be delivered sequentially at various ports in a thin-film single deposition.

Alternately, a mixture of reactant gases, for example, a mixture of metal precursor materials or a mixture of metal and non-metal precursors may be applied at a single output channel when making complex thin film materials, for example, having alternate layers of metals or having lesser amounts of dopants admixed in a metal oxide material. The critical requirement is that an inert stream labeled I should separate any reactant channels in which the gases are likely to react with each other. First and second reactant gaseous materials O and M react with each other to effect ALD deposition, but neither reactant gaseous material O nor M reacts with inert gaseous material I.

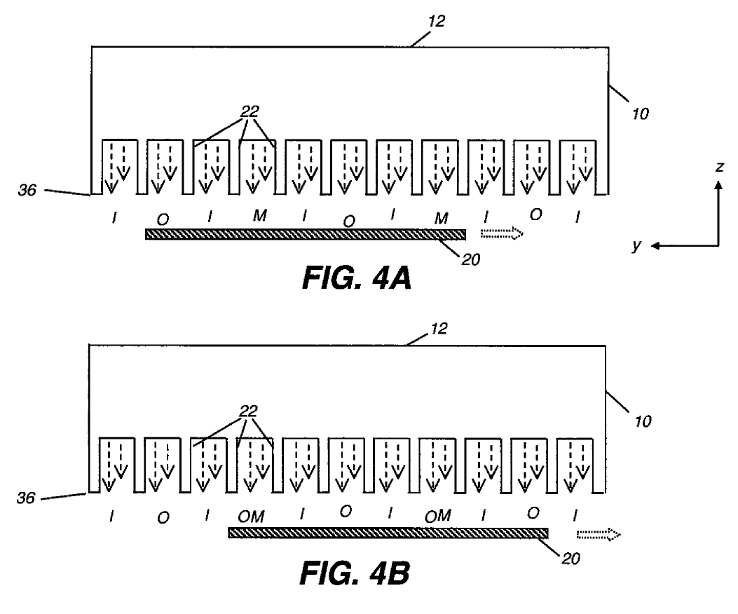

The cross-sectional views of FIGS. 4A and 4B show, in simplified schematic form, the ALD coating operation performed as substrate 20 passes along output face 36 of distribution manifold 10 when delivering reactant gaseous materials O and M. In FIG. 4A, the surface of substrate 20 first receives an oxidizing material from output channels 12 designated as delivering first reactant gaseous material O. The surface of the substrate now contains a partially reacted form of material O, which is susceptible to reaction with material M. Then, as substrate 20 passes into the path of the metal compound of second reactant gaseous material M, the reaction with M takes place, forming a metallic oxide or some other thin film material OM that can be formed from two reactant gaseous materials.

As FIGS. 4A and 4B show, inert gaseous material I is provided in every alternate output channel 12, between the flows of first and second reactant gaseous materials O and M. Sequential output channels 12 are adjacent, that is, share a common boundary, formed by partitions 22 in the embodiments shown. Here, output channels 12 are defined and separated from each other by partitions 22 that extend perpendicular to the surface of substrate 20.

Notably, there are no vacuum channels interspersed between the output channels 12, that is, no vacuum channels on either side of a channel delivering gaseous materials to draw the gaseous materials around the partitions. This advantageous, compact arrangement is possible because of the innovative gas flow that is used. Unlike gas delivery arrays of earlier processes that apply substantially vertical (that is, perpendicular) gas flows against the substrate and should then draw off spent gases in the opposite vertical direction, distribution manifold 10 directs a gas flow (preferably substantially laminar in one embodiment) along the surface for each reactant and inert gas and handles spent gases and reaction by-products in a different manner. The gas flow used in the present invention is directed along and generally parallel to the plane of the substrate surface. In other words, the flow of gases is substantially transverse to the plane of a substrate rather than perpendicular to the substrate being treated.

The above described method and apparatus, known as atmospheric pressure atomic layer deposition (AP-ALD), is one example of a vapor deposition process that can by used in the present invention to create a layer of aluminium oxide on the surface of an inkjet printed image to reduce image fade. Other vapor deposition methods may be used, for example CVD. In addition, alternative deposition techniques such as sputtering may be used to deposit the layer of aluminium oxide.

In a desirable embodiment, an inkjet printer is equipped to provide a deposit of the Al₂O₃ containing material over the printed image. Desirably, the net solids of the Al₂O₃ material is primarily Al₂O₃.

### EXAMPLE

Four pieces of commercially available porous inkjet media (Kodak Everyday Picture Paper) were taken and an image comprising stripes of colors was printed onto each using an HP Deskjet 903C printer and the appropriate dye based inks using the following printer settings:
Media setting: HP Premium Plus Photo Paper
Quality setting: Best
Color setting: Color

One of these samples was treated as the comparison (control), while on the other samples, layers of Al₂O₃ of various thicknesses were deposited on top of the printed image using AP-ALD. Coating A had a 5 nm Al₂O₃ layer deposited on top of the printed image, coating B had a 15 nm Al₂O₃ layer deposited on top of the printed image using AP-ALD and coating C had a 30 nm Al₂O₃ layer deposited on top of the printed image using AP-ALD. The conditions used for the depositions are shown in Table 1.

TABLE 1
AP-ALD conditions used to deposit Al₂O₃ layer

| | | |
|---|---|---|
| Bubbler 1 | Material | Water |
| | Flow rate | 22 ml/min |
| Bubbler 2 | Material | Trimethyl aluminium |
| | Flow rate | 48 ml/min |
| Carrier gas flow | Inert (N₂) | 2000 ml/min |
| | Water (compressed air) | 300 ml/min |
| | Metal (N₂) | 200 ml/min |
| Temperature | Platen | 95-105° C. |
| | Coating Head | 50° C. |
| Deposition Settings | Platen speed | 50 mm/sec |
| | Head height | 55 μm |
| Cell A | No. of oscillations | 50 |
| | Thickness of Al₂O₃ Layer | ~5 nm |
| Cell B | No. of oscillations | 100 |
| | Thickness of Al₂O₃ Layer | ~15 nm |
| Cell C | No. of oscillations | 200 |
| | Thickness of Al₂O₃ Layer | ~30 nm |

Printed densities were then measured for each color on both the control and the coatings A, B and C (examples of the invention) using an X-rite densitometer. The samples were then placed in a window for 8 weeks to allow the images to fade. After this period of time, the densities were re-measured. Table 2 shows the % loss of density for each color for both the control and the coatings A, B and C (examples of the invention).

TABLE 2
% loss of printed density after 8 weeks natural fading

| | Black | Cyan | Magenta | Yellow | Red | Green | Blue |
|---|---|---|---|---|---|---|---|
| Control | −13.92 | −36.96 | −13.61 | −8.49 | −16.86 | −24.01 | −17.19 |
| 5 nm Al₂O₃ layer | −11.43 | −34.74 | −13.58 | −7.33 | −16.49 | −23.31 | −13.91 |
| 15 nm Al₂O₃ layer | −11.76 | −32.23 | −13.24 | −5.76 | −15.67 | −23.68 | −11.82 |
| 30 nm Al₂O₃ layer | −9.53 | −29.57 | −9.36 | −5.72 | −14.21 | −19.99 | −10.85 |

This example demonstrates that image fade obtained when dye based inks are used to print an inkjet image on porous inkjet media can be reduced by depositing a very thin layer of Al₂O₃ by AP-ALD on top of the printed image. For some of the colors a layer as thin as 5 nm of Al₂O₃ is beneficial, but to achieve the largest improvement, a 30 nm layer is required.

It will be understood by those skilled in the art that the invention is not limited to use on a porous media. The invention is equally applicable to swellable media. It will also be understood by those skilled in the art that the invention is not limited to using atmospheric pressure atomic layer deposition to lay down the aluminium dioxide. Any other vapor deposition may be used or other methods such as sputtering.

The invention has been described in detail with reference to preferred embodiments thereof. It will be understood by those skilled in the art that variations and modifications can be effected within the scope of the invention.

### PARTS LIST

1 continuous supply of gaseous materials for system (reactants and inert gas)
2 first channel transverse flow of first molecular precursor over channel area of substrate
3 relative movement of substrate and multi-channel flows
4 second channel (purge) transverse flow with inert gas over channel area
5 relative movement of substrate and multi-channel flows
6 third channel transverse flow of second molecular precursor over channel area
7 relative movement of substrate and multi-channel flows
8 fourth channel (purge) transverse flow with inert gas over channel area
9 relative movement of substrate and multi-channel flow
10 distribution manifold
11 multiple channel flow in parallel
12 output channels
14 gas inlet port
15 sequence
16 gas inlet port
18 gas inlet port
20 substrate
22 partitions
36 output face
D distance
I third inert gaseous material
M second reactant gaseous material
O first reactant gaseous material
OM other thin film material formed from two reactant gaseous materials
R arrow

1. A method of reducing dye fade of a printed inkjet image comprising the step of depositing a layer of Al₂O₃ over the image.

2. The method as claimed in claim 1, wherein the layer of Al₂O₃ has a thickness of 30 nm or less.

3. The method as claimed in claim 1, wherein the layer of Al₂O₃ is deposited over the image by vapor deposition.

4. The method as claimed in claim 3, wherein the layer of Al₂O₃ is deposited over the image by atmospheric pressure atomic layer deposition.

5. The method as claimed in claim 4, wherein the layer of Al₂O₃ is deposited over the image by simultaneously directing a series of gas flows along elongated channels such that the gas flows are substantially parallel to a surface of the image and substantially parallel to each other, whereby the gas flows are substantially prevented from flowing in the direction of the adjacent elongated channels, and wherein the series of gas flows comprise, in order, at least a first reactive gaseous material, inert purge gas, and a second reactive gaseous material, wherein the first reactive gaseous material is capable of reacting with a substrate surface treated with the second reactive gaseous material.

6. The method as claimed in claim 1, wherein the layer of Al₂O₃ is deposited over the image by sputtering.

7. The method as claimed in claim 1, wherein the inkjet image is printed on a porous substrate.

8. A printed inkjet image comprising a layer containing Al₂O₃ over the image.

9. The printed image of claim 8, wherein the Al₂O₃-layer is at least 5 nm thick.

10. The printed image of claim 8, wherein the Al₂O₃-containing layer consists primarily of Al₂O₃.

11. An inkjet printer comprising a depositable source of Al₂O₃.

12. The inkjet printer of claim 11 wherein the source of Al₂O₃ contains net solids that are primarily Al₂O₃.
